(19) United States
(12) Patent Application Publication
(10) Pub. No.: US 2025/0215221 A1
(43) Pub. Date: Jul. 3, 2025

(54) LOW DIELECTRIC HIGH TG RESIN COMPOSITION FOR IMPROVEMENT OF PROCESSABILITY, PREPREG AND METAL CLAD LAMINATE

(71) Applicant: NAN YA PLASTICS CORPORATION, TAIPEI (TW)

(72) Inventors: TE-CHAO LIAO, TAIPEI (TW); WEI-RU HUANG, TAIPEI (TW); HUNG-YI CHANG, TAIPEI (TW); CHIA-LIN LIU, TAIPEI (TW); Ren-Yu Liao, New Taipei City (TW)

(21) Appl. No.: 18/614,370

(22) Filed: Mar. 22, 2024

(30) Foreign Application Priority Data
Dec. 27, 2023 (TW) 112150986

(51) Int. Cl. C08L 71/12; C08J 5/24

(52) U.S. Cl. CPC C08L 71/123; C08J 5/244; C08J 2371/12; C08J 2445/00; C08J 2447/00

(57) ABSTRACT

A low dielectric high Tg resin composition includes a resin system, a halogen-free flame retardant, a coupling agent, and an inorganic filler. The resin system includes a low dielectric resin, a crosslinking agent, and a polyindene resin which are each added in a specific weight percentage. The low dielectric resin is formed from a monomer composition including styrene, divinylbenzene, and ethylene. Therefore, the low dielectric high Tg resin composition has a glass transition temperature not less than 200° C., and the low dielectric high Tg resin composition after being cured has a dielectric constant (Dk) between 3.0 and 3.2 and a dielectric loss factor (Df) less than 0.0013 at 10 GHz. Based on the above, a prepreg and a metal clad laminate applying the low dielectric high Tg resin composition are further provided.

### CROSS-REFERENCE TO RELATED PATENT APPLICATION

This application claims the benefit of priority to Taiwan Patent Application No. 112150986, filed on Dec. 27, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a resin composition and its applications, and more particularly to a low dielectric high Tg resin composition and a prepreg and a metal clad laminate prepared by using the low dielectric high Tg resin composition.

### BACKGROUND OF THE DISCLOSURE

5G communication can achieve faster and lower latency transmission effects due to its high frequency and short wavelength characteristics. In the current application field of 5G, the most significant characteristics are the dielectric constant and dissipation factor of materials. Materials with low dielectric properties can cause a decrease in signal loss and heat generation. Therefore, materials with low dielectric properties are being actively developed for meeting requirements in application.

Among resin materials, polytetrafluoroethylene (PTFE) and polyphenylene ether (PPO/PPE) have particularly attracted attention because of their low dielectric constant and loss factor. However, PTFE has not only poor processability but also poor bonding strength to a copper foil, and is thus disadvantageous for manufacturing circuit boards with a high density interconnection design and a large number of layers. PPE has better processability than PTFE, and has become one of the main alternatives to PTFE. Therefore, low dielectric materials that are currently developed with PPE as a main component (i.e., a main part of resin formula) has been adopted by many copper foil substrate (CCL) manufacturers.

High speed products such as high-end server products pay more attention to the dielectric loss of substrates. However, the loss factor in the low dielectric material with PPE as a main component (i.e., a main part of resin formula) is difficult to be reduced to a lower level, gradually making such low dielectric materials incapable of meeting practical requirements. Although PPE can be used in combination with different types of low dielectric resins to reduce loss factor, it can easily cause the lowering of glass transition temperature (Tg), thus resulting in limitations in application.

Therefore, developing a low dielectric material with a low dielectric constant, a low loss factor and a high glass transition temperature has become an urgent goal in the relevant field.

### SUMMARY OF THE DISCLOSURE

In response to the above-referenced technical inadequacies, the present disclosure provides a low dielectric high Tg resin composition, which can be applied to a substrate after being cured and is advantageous for high-frequency and high-speed signal transmission and long-term reliability of the substrate. The present disclosure further provides a prepreg and a metal clad laminate applying the low dielectric high Tg resin composition.

In order to solve the above-mentioned problems, one of the technical aspects adopted by the present disclosure is to provide a low dielectric high Tg resin composition, which includes component (A) of a resin system, component (B) of a halogen-free flame retardant, component (C) of a coupling agent, and component (D) of an inorganic filler. The resin system includes 10 wt % to 40 wt % of a low dielectric resin, 5 wt % to 20 wt % of a crosslinking agent, and 10 wt % to 70 wt % of a polyindene resin, based on a total weight of the resin system. The low dielectric resin is formed from a monomer composition including styrene, divinylbenzene, and ethylene. In the low dielectric high Tg resin composition, with respect to 100 phr of the resin system, an amount of the halogen-free flame retardant ranges from 20 phr to 45 phr, an amount of the coupling agent ranges from 0.05 phr to 5 phr, and an amount of the inorganic filler ranges from 50 phr to 120 phr. Furthermore, the low dielectric high Tg resin composition has a glass transition temperature not less than 200° C. The low dielectric high Tg resin composition after being cured has a dielectric constant (Dk) between 3.0 and 3.2 and a dielectric loss factor (Df) less than 0.0013 at 10 GHz.

In one of the possible or preferred embodiments, the polyindene resin has a number average molecular weight between 300 g/mol and 1000 g/mol.

In one of the possible or preferred embodiments, the polyindene resin contains at least two reactive functional groups among acrylic, styrene, and maleimide groups.

In one of the possible or preferred embodiments, the low dielectric resin has a number average molecular weight between 4500 g/mol and 6500 g/mol.

In one of the possible or preferred embodiments, the low dielectric resin has a styrene unit between 10 mol % and 40 mol %, a divinylbenzene unit content between 10 mol % and 40 mol %, and an ethylene unit content between 10 mol % and 20 mol %, based on a total amount of all monomer units of the low dielectric resin being 100 mol %.

In one of the possible or preferred embodiments, the inorganic filler is silica prepared by a synthesis method and having an average particle size (D50) between 2.0 μm and 3.0 μm.

In one of the possible or preferred embodiments, the silica a specific gravity between 2.0 g/cm³ and 2.5 g/cm³.

In one of the possible or preferred embodiments, the halogen-free flame retardant is a compound having the structure represented by formula (I):

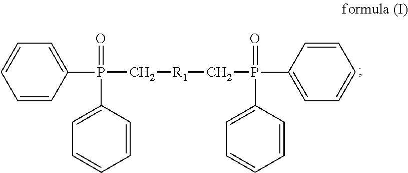

in formula (I), R1 represents a covalent bond, —CH2-,

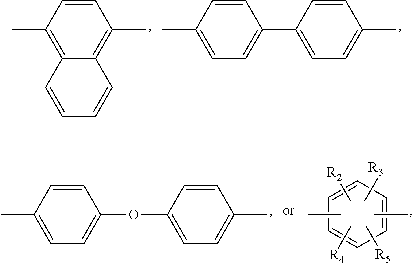

in which R₂, R₃, R₄, and R₅ each independently represent a hydrogen atom, an alkyl group, or

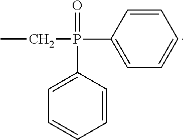 [SMILES: CCP(=O)(c1ccccc1)c1ccccc1]

In one of the possible or preferred embodiments, the crosslinking agent is selected from the group consisting of 1,3,5-triallyl cyanurate (TAC), triallyl isocyanurate (TAIC), trimethallyl isocyanurate (TMAIC), diallyl phthalate, divinylbenzene, and 1,2,4-triallyl trimellitate.

In order to solve the above-mentioned problems, another one of the technical aspects adopted by the present disclosure is to provide a prepreg, which is prepared by coating or impregnating a reinforcing material with the low dielectric high Tg resin composition.

In order to solve the above-mentioned problems, yet another one of the technical aspects adopted by the present disclosure is to provide a metal clad laminate, which is prepared by laminating the prepreg to a metal layer or by coating the low dielectric high Tg resin composition on a metal layer.

In conclusion, by virtue of the resin system including 10 wt % to 40 wt % of a low dielectric resin, 5 wt % to 20 wt % of a crosslinking agent, and 10 wt % to 70 wt % of a polyindene resin, based on a total weight of the resin system and the low dielectric resin formed from a monomer composition including styrene, divinylbenzene, and ethylene monomers, the low dielectric high Tg resin composition provided by the present disclosure can achieve excellent low electrical properties (low Dk/low Df) at high frequencies, especially Df<0.0013, thereby ensuring stable performance on low transmission loss for a long period of time, and can maintain a glass transition temperature (Tg) at 200° C. or above, thereby improving practical substrate properties such as water absorption, heat resistance, and peeling strength.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 and FIG. 2 are each a schematic view showing a practical application of a low dielectric high Tg resin composition for improvement of processability of the present disclosure; and

FIG. 3 to FIG. 5 are each a schematic view showing a metal clad laminate manufactured by using the low dielectric high Tg resin composition for improvement of processability of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Unless otherwise stated, the material(s) used in any described embodiment is/are commercially available material(s) or may be prepared by methods known in the art, and the operation(s) or instrument(s) used in any described embodiment is/are conventional operation(s) or instrument(s) generally known in the related art.

Conventional dielectric materials are provided on the basis of a polyphenylene ether resin and are thus difficult to reduce the dielectric loss factor to a lower level. Although a novel low dielectric resin of polydivinylbenzene (PDVB) can be used in combination to reduce the dielectric loss factor, it also causes a lowering of the glass transition temperature (Tg). Thus, the conventional dielectric materials are limited to practical applications. Therefore, the present disclosure provides an inventive concept as follows: a low dielectric resin containing styrene, divinylbenzene, and ethylene units is used in combination with a polyindene resin, thereby meeting low dielectric loss properties while maintaining a sufficient glass transition temperature (Tg).

More specifically, the present disclosure provides a low dielectric high Tg resin composition, which embodies the inventive concept and includes: component (A), a resin system; component (B), a halogen-free flame retardant; component (C), a coupling agent, and component (D), an inorganic filler. More details about each component are described below.

### Component (A) of Resin System

The resin system forming the low dielectric high Tg resin composition of the present disclosure includes 10 wt % to 40 wt % of a low dielectric resin, 5 wt % to 20 wt % of a crosslinking agent, and 10 wt % to 70 wt % of a polyindene resin, based on a total weight of the resin system.

In one embodiment of the present disclosure, the low dielectric resin is essentially a copolymer containing alkenyl monomers, which is formed from a monomer composition including styrene, divinylbenzene, and ethylene monomers. The divinylbenzene unit serving as a monomeric unit in the low dielectric resin can function to increase the glass transition temperature (Tg). The ethylene unit serving as a monomeric unit in the low dielectric resin can function to reduce the dielectric dissipation factor (Df). The styrene unit serving as a monomeric unit in the low dielectric resin can function to maintain good heat resistance.

Preferably, the low dielectric resin has a styrene unit between 10 mol % and 40 mol %, a divinylbenzene unit content between 10 mol % and 40 mol %, and an ethylene unit content between 10 mol % and 20 mol %, based on a total amount of all monomer units of the low dielectric resin being 100 mol %, thereby balancing the low dielectric properties and the glass transition temperature of applied substrate materials.

In practice, with respect to a total weight of the resin system being 100 wt %, an amount of the low dielectric resin can be 10 wt %, 15 wt %, 20 wt %, 25 wt %, 30 wt %, 35 wt %, or 40 wt %. Furthermore, the low dielectric resin has a number average molecular weight between 4500 g/mol and 6500 g/mol.

In one embodiment of the present disclosure, the polyindene resin can synergistically interact with the low dielectric resin to reduce the dielectric loss factor (Df) while maintaining the glass transition temperature (Tg) at 200° C. or above. It is worth mentioning that the polyindene resin can serve as a modifier to improve the processability, stability, thermal properties, viscoelasticity, rheology, adhesion, and/or mechanical properties of the resin composition.

Preferably, the polyindene resin contains at least two reactive functional groups among acrylic, styrene, and maleimide groups and is thus advantageous for forming a three-dimensional network structure and achieving required physicochemical properties, such as high glass transition temperature, low water absorption, and good heat resistance.

In practice, with respect to a total weight of the resin system being 100 wt %, an amount of the polyindene resin can be 10 wt %, 15 wt %, 20 wt %, 25 wt %, 30 wt %, 35 wt %, 40 wt %, 45 wt %, 50 wt %, 55 wt %, 60 wt %, 65 wt %, or 70 wt %. The polyindene resin can contain more than 90% of indene repeating units on a molecular main chain thereof. Furthermore, the polyindene resin has a number average molecular weight between 300 g/mol and 1000 g/mol, and can be partially or fully hydrogenated to regulate aromaticity, which is advantageous for improving compatibility.

In one embodiment of the present disclosure, the crosslinking agent is a component that has at least one unsaturated functional group containing a double or triple bond, so as to undergo a crosslinking reaction to form a three-dimensional network structure. The crosslinking agent can be, but is not limited to, a monofunctional crosslinker that has only one unsaturated functional group in a molecule structure or a polyfunctional crosslinker that has more than two unsaturated functional groups in a molecule structure. There is no restriction on the type of the crosslinking agent, and the crosslinking agent is preferably one that has good compatibility with a resin component as mentioned above.

More specifically, the crosslinking agent used for the resin system as component (A) can be selected from the group consisting of 1,3,5-triallyl cyanurate (TAC), triallyl isocyanurate (TAIC), trimethallyl isocyanurate (TMAIC), diallyl phthalate, divinylbenzene, and 1,2,4-triallyl trimellitate. These crosslinking agents can be used individually or in combination.

With respect to the total weight of the resin system being 100 wt %, an amount of the crosslinking agent can be 5 wt %, 10 wt %, 15 wt %, 20 wt %, 25 wt %, or 30 wt %.

In one embodiment of the present disclosure, the resin system as component (A) can further include at least one polyphenylene ether resin having a molecule main chain that contains an unsaturated functional group at each of terminal ends, if necessary, such as hydroxy, vinyl, styryl, vinylbenzyl, allyl, acryloyl, methacrylate, epoxy, and maleimide groups. Said unsaturated functional group means a group capable of undergoing an addition polymerization reaction with other components having an unsaturated functional group, and said addition polymerization reaction may be initiated by light or heat in the presence of a polymerization initiator.

More specifically, the at least one polyphenylene ether resin used for the resin system as component (A) can be selected from the group consisting of the following: a polyphenylene ether resin containing terminal hydroxyl groups, a polyphenylene ether resin containing terminal vinyl groups, a polyphenylene ether resin containing terminal styryl groups, a polyphenylene ether resin containing terminal vinylbenzyl groups, a polyphenylene ether resin containing terminal allyl groups, a polyphenylene ether resin containing terminal acryloyl groups, a polyphenylene ether resin containing terminal methacrylate groups, a polyphenylene ether resin containing terminal epoxy groups, and a polyphenylene ether resin containing terminal maleimide groups. These polyphenylene ether resins can be used individually or in combination.

With respect to a total weight of the resin system being 100 wt %, an amount of the at least one polyphenylene ether resin can be from 20 wt % to 60 wt %. It is worth noting that in the presence of the polyindene resin, the amount of the at least one polyphenylene in resin system can be significantly reduced, and can even be reduced to 0% (i.e., completely omitted).

The polyphenylene ether resin can have a weight average molecular weight between 1000 g/mol and 20000 g/mol, and preferably between 1000 g/mol and 10000 g/mol. If the molecular weight of the polyphenylene ether resin is too large, the fluidity and solvent solubility of the polyphenylene ether resin may become worse. If the molecular weight of the polyphenylene ether resin is too small, the electrical properties and thermal stability of the resin composition may be negatively affected.

In practice, two different polyphenylene ether resins can be used in combination in the resin system as component (A), such as a polyphenylene ether resin having a molecule main chain with terminal maleimide groups and a polyphenylene ether resin having a molecule main chain with terminal hydroxy, styryl, methacrylate, or epoxy groups. Alternatively, three different polyphenylene ether resins can be used in combination in the resin system as component (A), such as a polyphenylene ether resin having a molecule main chain with terminal maleimide groups, a polyphenylene ether resin having a molecule main chain with terminal styryl groups, and a polyphenylene ether resin having a molecule main chain with terminal methacrylate groups.

The method for preparing the above-mentioned polyphenylene ether resin(s) having an unsaturated functional group is not the primary technical feature of the present disclosure, and people having ordinary skill in the art can carry out the method based on the present disclosure.

### Component (B) of Halogen-Free Flame Retardant

The halogen-free flame retardant forming the low dielectric high Tg resin composition of the present disclosure can be a phosphorus-containing flame retardant, so as to increase flame resistance of a resulting electronic material and meet the requirements of halogen-free environmental protection. In practice, the phosphorus-containing flame retardant can be selected from the group consisting of a phosphate ester flame retardant, a phosphazene flame retardant, a phosphine oxide flame retardant, ammonium polyphosphate, melamine polyphosphate, melamine phosphate, and 9,10-dihydro-9-oxa-10-phosphaphenanthrene-10-oxide (DOPO). These halogen-free flame retardants can be used individually or in combination. However, such examples are not intended to limit the present disclosure.

Specific examples of the phosphate ester flame retardant include triphenyl phosphate (TPP), tetraphenyl resorcinol bis(diphenylphosphate) (RDP), bisphenol A bis(diphenylphosphate) (BDP), and Resorcinol bis(di-2,6-xylyl phosphate) (RXP).

Specific examples of the phosphazene flame retardant include cyclic and linear phosphazene compounds.

Specific examples of the phosphine oxide flame retardant include tris(4-methoxyphenyl)phosphine oxide, diphenylphosphine oxide, triphenylphosphine oxide, and a phosphine oxide compound having the structure represented by formula (I) (the product with model name PQ-60 available from Chin-Yee Chemical Industries Co., Ltd.). It is worth mentioning that in addition to known flame-retardant properties, the phosphine oxide compound having the structure represented by formula (I) also functions to improve low dielectric properties of the resin composition, which is beneficial for high frequency applications.

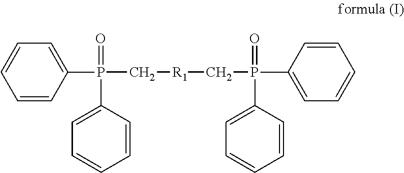

In formula (I), R₁ represents a covalent bond, —CH₂—,

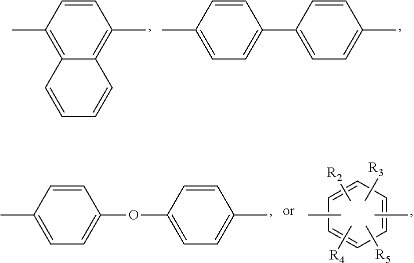

in which R₂, R₃, R₄, and R₅ each independently represent a hydrogen atom, an alkyl group, or

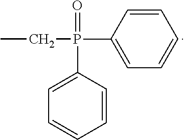 [SMILES: CCP(=O)(c1ccccc1)c1ccccc1]

With respect to 100 phr of the resin system as component (A), an amount of the halogen-free flame retardant as component (B) can be in the range from 20 phr to 45 phr, such as 20 phr, 25 phr, 30 phr, 35 phr, 40 phr, or 45 phr. If the amount of the halogen-free flame retardant is less than 20 phr, an electronic material made of the resin composition cannot achieve desired flame resistance. If the amount of the halogen-free flame retardant is greater than 45 phr, properties required for practical use may be negatively affected, such as electrical properties, water absorbance, and tear strength.

### Component (C) of Coupling Agent

The coupling agent forming the low dielectric high Tg resin composition of the present disclosure can be at least one of a silane compound and a siloxane compound, so as to increase interfacial bonding strength between a resin and a reinforcing material such as a fiber cloth and improve compatibility between the resin and inorganic powders.

Specific examples of the silane compound include amino silane, vinyl silane, acrylic silane, and epoxy silane. Specific examples of the siloxane compound include amino siloxane, vinyl siloxane, acrylic siloxane, and epoxy siloxane.

With respect to 100 phr of the resin system as component (A), an amount of the coupling agent as component (C) can be in the range from 0.05 phr to 1 phr, and preferably from 0.3 phr to 0.7 phr.

In certain embodiments, with respect to 100 phr of the resin system as component (A), an amount of the coupling agent as component (D) can be 0.05 phr, 0.1 phr, 0.2 phr, 0.3 phr, 0.4 phr, 0.5 phr, 0.6 phr, 0.7 phr, 0.8 phr, 0.9 phr, or 1 phr.

### Component (D) of Inorganic Filler

The at least one inorganic filler forming the low dielectric high Tg resin composition of the present disclosure can be selected from the group consisting of the following: silica, aluminum oxide, zinc oxide, titanium oxide, magnesium oxide, antimony oxide, beryllium oxide, aluminum nitride, boron nitride, calcium carbonate, potassium titanate, glass fiber, barium titanate, barium sulfate, aluminum hydroxide, and magnesium hydroxide. These inorganic fillers can be used individually or in combination. Therefore, the dielectric constant and dielectric loss can be maintained at a lower level, and the mechanical strength, thermal conductivity, and heat resistance of the resin composition can be improved. However, such examples are not intended to limit the present disclosure.

Preferably, the at least one inorganic filler as component (D) is spherical silica that can be prepared by using a synthesis method. Furthermore, the spherical silica has a specific gravity between 2.0 g/cm³ and 2.5 g/cm³ and an average particle size (D50) between 2.0 μm and 3.0 μm. The specific gravity of the spherical silica is preferably 2.2 g/cm³. In addition, the spherical silica can be surface-modified by at least one of an acrylic group and a vinyl group, thereby having good compatibility with the resin system as component (A), and can thus be added to the resin composition in a greater amount without negatively affecting properties required for practical use.

With respect to 100 phr of the resin system, an amount of the at least one inorganic filler as component (D) can be in the range from 50 phr to 120 phr, preferably from 80 phr to 110 phr, and more preferably from 90 phr to 110 phr.

In certain embodiments, with respect to 100 phr of the resin system as component (A), the amount of the at least one inorganic filler as component (D) can be 50 phr, 55 phr, 60 phr, 65 phr, 70 phr, 75 phr, 80 phr, 85 phr, 90 phr, 95 phr, 100 phr, 105 phr, 110 phr, 115 phr, or 120 phr.

### Prepreg and Metal Clad Laminate

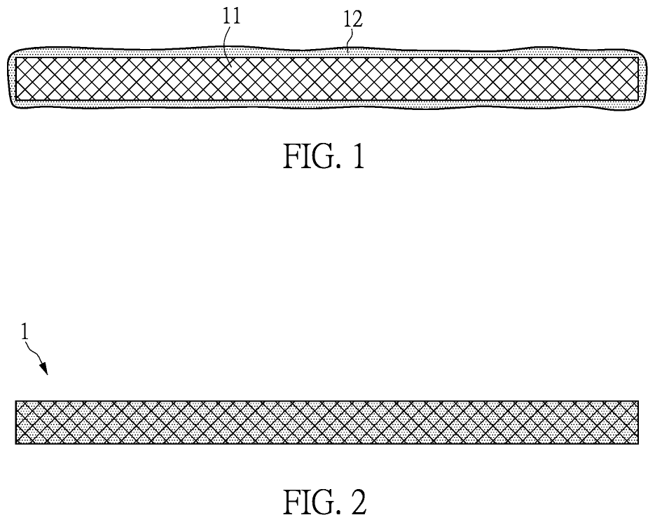

Referring to FIG. 1 and FIG. 2, the present disclosure further provides a prepreg 1 and a metal clad laminate applying the low dielectric high Tg resin composition as described above. More specifically, the prepreg 1 is prepared by the method as follows. The reinforcing material 11 is coated or impregnated with a low dielectric high Tg resin composition 12, in which the low dielectric high Tg resin composition 12 is attached to the reinforcing material 11. Afterwards, the low dielectric high Tg resin composition 12 is caused to be in a semi-cured state by heating at a high temperature. The reinforcing material 11 is, for example, an electronic-grade general-purpose fiberglass cloth.

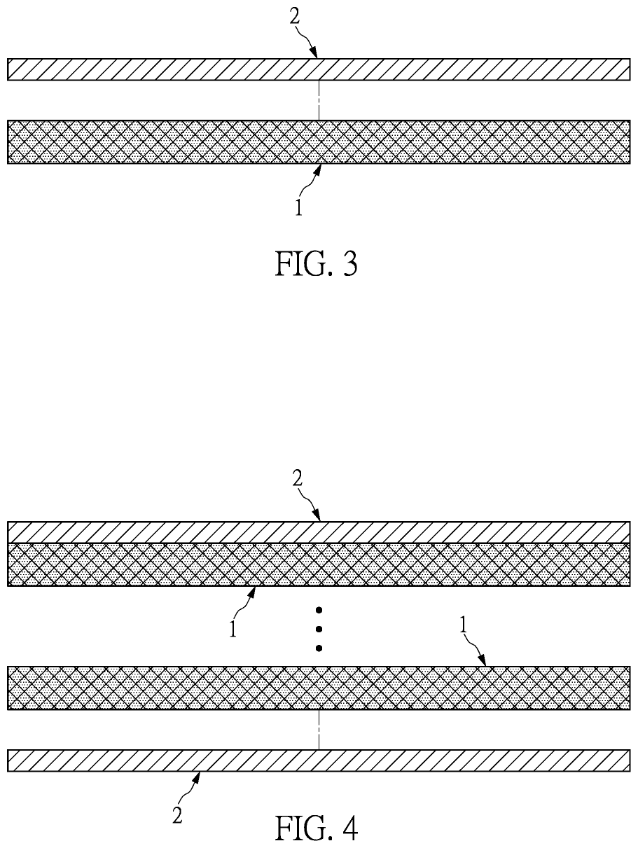

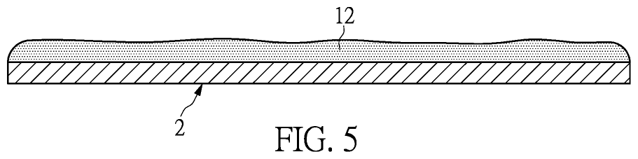

Referring to FIG. 3 to FIG. 5, the metal clad laminate can be prepared by the method as follows. One or more prepregs 1 are laminated with at least one metal layer 2 (e.g., a copper layer) and bonded together by hot pressing. Alternatively, the low dielectric high Tg resin composition 12 is coated on a metal layer 2 and cured after being fully dried. In one embodiment of laminating one or more prepregs 1 with at least one metal layer 2 (e.g., a copper layer), a number of prepregs 1 can be formed into a laminate′, and a metal layer 2 can be laminated on at least one outer side of the laminate 1′.

In practice, the metal layer 2 of the metal clad laminate can be patterned by conventional process steps to obtain a printed circuit board.

### Performance Evaluation

The resin compositions as shown in Table 1 and Table 2 are each formed into a thermosetting resin varnish by using toluene. Each of the resin compositions is used to impregnate four Nan-Ya fiber glass cloth (the product with model name NE1078 available from Nan Ya Plastics Corporation) serving as reinforcing materials at room temperature. After drying at 130° C. for a few minutes, the four prepregs resulting from each of the resin compositions are obtained and each have a resin content of 70 wt %. Afterwards, the four prepregs resulting from each of the resin compositions are laminated between two copper foils having a thickness of 35 μm for hot pressing. The hot pressing is carried out at a temperature of 85° C. and under a pressure of 25 kg/cm², and the temperature is maintained for 20 minutes. Next, the temperature is heated to 210° C. at a heating rate of 3° C./min, maintained for 120 minutes, and slowly cooled to 130° C. Thus, a copper foil substrate sample resulting from each of the resin compositions and having a thickness of 0.4 mm is obtained and evaluated for performance according to the following conditions.

Glass transition temperature (° C.): testing the glass transition temperature by a dynamic mechanical analyzer (DMA).

Water absorption rate (%): heating the copper foil substrate sample in a 2-atm pressure cooker at 120° C. for 120 minutes and calculating the change in weight loss of the copper foil substrate sample after heating.

Solder heat resistance (288° C.): after the copper foil substrate sample is heated in a 2-atm pressure cooker at 120° C. for 120 minutes, immersing the copper foil substrate sample in a solder bath at 288° C. and observing the copper foil substrate sample at ½ hour and 2 hours. If cracking or interlayer delamination in the copper foil substrate sample is observed, the copper foil substrate sample is regarded as “NG”. If no cracking or interlayer delamination in the copper foil substrate sample is observed, the copper foil substrate sample is regarded as “Pass”.

Dielectric constant (10 GHZ) and Dielectric dissipation factor (10 GHz): after the copper foils are removed from the copper foil substrate sample and a baking process in a 105° C. oven is subsequently performed on the sample for 30 minutes, detecting the dielectric constant and the dielectric dissipation factor of the copper foil substrate sample at 10 GHz by an dielectric analyzer (the product with model name E4991A available from Agilent Technologies, Inc).

Plated copper uniformity of drilled hole: after a hole drilling process is performed on the copper foil substrate sample, analyzing the copper foil substrate sample by cross-sectioning and using a scanning electron microscope (SEM) to observe the plated copper uniformity in drilled holes.

In Table 1 and Table 2, details of raw materials are provided below:

Low dielectric resin: the product with model name Poly-DVB available from Denka Company.
Polyindene resin: the product with model name NE-X-9480 available from Nippon DIC Company (Japan).
PPE resin: the product with model name MX9000 available from SABIC Company.
First BMI resin: the product with model name MIR-3000-70MT available from Nippon Kayaku Company.
Second BMI resin: the product with model name MIR-5000-60T available from Nippon Kayaku Company.
Crosslinking agent: TAIC available from Evonik Company.
Flame retardant: the product with model name PQ-60 available from Chin-Yee Chemical Industries Company.
Spherical silica: silica prepared by a synthesis method, which is the product with model name EQ2410-SMC available from Third Age Technology (TAT) Company (China).
Coupling agent: the product with model name Z-6030 available from Dow Corning Company.
Peroxide: the product with model name Luperox F available from Arkema Company.

TABLE 1

| | | Comparative Examples | | |
|---|---|---|---|---|
| Items (Content: parts by weight) | | 1 | 2 | 3 |
| Raw | PPE resin | 60 | 40 | 40 |
| materials | Polyindene resin | | | |
| | Low dielectric resin | 25 | 25 | 25 |
| | First BMI resin | | 20 | |
| | Second BMI resin | | | 20 |
| | Crosslinking agent | 15 | 15 | 15 |
| | Flame retardant | 30 | 30 | 30 |
| | Spherical silica | 52 | 52 | 52 |
| | Coupling agent | 0.5 | 0.5 | 0.5 |
| | Peroxide | 1 | 1 | 1 |
| Evaluation | Glass transition | 212 | 256 | 243 |
| results | temperature (° C.) | | | |
| | Water absorption (%) | 0.18 | 0.23 | 0.21 |
| | (PCT a half hour) | | | |
| | Heat resistance | Pass | Pass | Pass |
| | (PCT a half hour) | | | |
| | Water absorption (%) | 0.24 | 0.32 | 0.29 |
| | (PCT two hours) | | | |
| | Heat resistance | Pass | Pass | Pass |
| | (PCT two hours) | | | |
| | Dk (10 GHz) | 3.06 | 3.12 | 3.11 |
| | Df (10 GHz) | 0.00148 | 0.00153 | 0.00149 |
| | Peeling strength (lb/in) | 3.56 | 3.83 | 3.18 |
| | (HVLP3, Hoz) | | | |

TABLE 2

| | | Examples | | |
|---|---|---|---|---|
| Items (Content: parts by weight) | | 1 | 2 | 3 |
| Raw | PPE resin | 40 | 20 | |
| materials | Polyindene resin | 20 | 40 | 60 |
| | Low dielectric resin | 25 | 25 | 25 |
| | First BMI resin | | | |
| | Second BMI resin | | | |
| | Crosslinking agent | 15 | 15 | 15 |
| | Flame retardant | 30 | 30 | 30 |
| | Spherical silica | 52 | 52 | 52 |
| | Coupling agent | 0.5 | 0.5 | 0.5 |
| | Peroxide | 1 | 1 | 1 |
| Evaluation | Glass transition | 210 | 206 | 201 |
| results | temperature (° C.) | | | |
| | Water absorption (%) | 0.18 | 0.19 | 0.20 |
| | (PCT a half hour) | | | |
| | Heat resistance | Pass | Pass | Pass |
| | (PCT a half hour) | | | |
| | Water absorption (%) | 0.25 | 0.26 | 0.28 |
| | (PCT two hours) | | | |
| | Heat resistance | Pass | Pass | Pass |
| | (PCT two hours) | | | |
| | Dk (10 GHz) | 3.07 | 3.08 | 3.11 |
| | Df (10 GHZ) | 0.00139 | 0.00133 | 0.00128 |
| | Peeling strength (lb/in) | 3.78 | 3.86 | 4.01 |
| | (HVLP3, Hoz) | | | |

It can be known from Table 1 and Table 2 that, the resin compositions of Comparative Examples 1 to 3 include a PPE resin added in combination with a low dielectric resin, rather than a polyindene resin, so that the Dk value of each of resulting substrates cannot be reduced to a level below 0.0014, or even below 0.0013, i.e., does not meet required low electrical properties (low Dk/low Df). Although the resin compositions of Comparative Examples 1 to 3 additionally include a BMI resin added to make the Tg of the resulting substrates higher, the BMI resin can cause an increase in Df value, resulting in a concern about increasing transmission loss. In comparison, the resin compositions of Examples 1 to 3 includes the polyindene resin added in combination with the low dielectric resin, as well as maintaining a glass transition temperature (Tg) at 200° C. or above, without lowering practically required properties such as water absorption and heat resistance. Furthermore, the resin compositions of Examples 1 to 3 can provide improved peeling strength to an applied substrate by using the polyindene resin.

### Beneficial Effects of the Embodiments

In conclusion, by virtue of the resin system including 10 wt % to 40 wt % of a low dielectric resin, 5 wt % to 20 wt % of a crosslinking agent, and 10 wt % to 70 wt % of a polyindene resin, based on a total weight of the resin system and the low dielectric resin formed from a monomer composition including styrene, divinylbenzene, and ethylene monomers, the low dielectric high Tg resin composition provided by the present disclosure can achieve excellent low electrical properties (low Dk/low Df) at high frequencies, especially Df<0.0013, thereby ensuring stable performance on low transmission loss for a long period of time, and can maintain a glass transition temperature (Tg) at 200° C. or above, thereby improving practical substrate properties such as water absorption, heat resistance, and peeling strength.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A low dielectric high Tg resin composition, comprising:
(A) a resin system including 10 wt % to 40 wt % of a low dielectric resin, 5 wt % to 20 wt % of a crosslinking agent, and 10 wt % to 70 wt % of a polyindene resin, based on a total weight of the resin system, wherein the low dielectric resin is formed from a monomer composition including styrene, divinylbenzene, and ethylene;
(B) a halogen-free flame retardant;
(C) a coupling agent; and
(D) an inorganic filler;
wherein, with respect to 100 phr of the resin system, an amount of the halogen-free flame retardant ranges from 20 phr to 45 phr, an amount of the coupling agent ranges from 0.05 phr to 5 phr, and an amount of the inorganic filler ranges from 50 phr to 120 phr;
wherein the low dielectric high Tg resin composition has a glass transition temperature not less than 200° C., and the low dielectric high Tg resin composition after being cured has a dielectric constant (Dk) between 3.0 and 3.2 and a dielectric loss factor (Df) less than 0.0013 at 10 GHz.

2. The low dielectric high Tg resin composition according to claim 1, wherein the polyindene resin has a number average molecular weight between 300 g/mol and 1000 g/mol.

3. The low dielectric high Tg resin composition according to claim 2, wherein the polyindene resin contains at least two reactive functional groups among acrylic, styrene, and maleimide groups.

4. The low dielectric high Tg resin composition according to claim 1, wherein the low dielectric resin has a number average molecular weight between 4500 g/mol and 6500 g/mol.

5. The low dielectric high Tg resin composition according to claim 4, wherein the low dielectric resin has a styrene unit between 10 mol % and 40 mol %, a divinylbenzene unit content between 10 mol % and 40 mol %, and an ethylene unit content between 10 mol % and 20 mol %, based on a total amount of all monomer units of the low dielectric resin being 100 mol %.

6. The low dielectric high Tg resin composition according to claim 1, wherein the inorganic filler is silica prepared by a synthesis method and having an average particle size (D50) between 2.0 μm and 3.0 μm.

7. The low dielectric high Tg resin composition according to claim 6, wherein the silica a specific gravity between 2.0 g/cm³ and 2.5 g/cm³.

8. The low dielectric high Tg resin composition according to claim 1, wherein halogen-free flame retardant is a compound having the structure represented by formula (I): 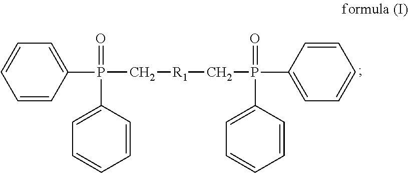
wherein R₁ represents a covalent bond, —CH₂—, 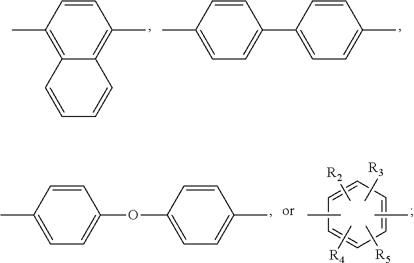
wherein R₂, R₃, R₄, and R₅ each independently represent a hydrogen atom, an alkyl group, or

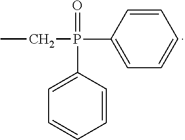 [SMILES: CCP(=O)(c1ccccc1)c1ccccc1]

9. The low dielectric high Tg resin composition according to claim 1, wherein the crosslinking agent is selected from the group consisting of 1,3,5-triallyl cyanurate (TAC), triallyl isocyanurate (TAIC), trimethallyl isocyanurate (TMAIC), diallyl phthalate, divinylbenzene, and 1,2,4-triallyl trimellitate.

10. A prepreg prepared by coating or impregnating a reinforcing material with the low dielectric high Tg resin composition as claimed in claim 1.

11. A metal clad laminate prepared by laminating the prepreg as claimed in claim 10 to a metal layer.

12. A metal clad laminate prepared by coating the low dielectric high Tg resin composition as claimed in claim 1 on a metal layer.
